(19) United States
(12) Patent Application Publication
(10) Pub. No.: US 2024/0322109 A1
(43) Pub. Date: Sep. 26, 2024

(54) MULTIWALLED CARBON NANOTUBES BASED FLEXIBLE AND BINDER--FREE ANODE FOR LI-ION BATTERIES

(71) Applicant: KING FAISAL UNIVERSITY, Al-Ahsa (SA)

(72) Inventors: FAHEEM AHMED, AL-AHSA (SA); NISHAT ARSHI, AL-AHSA (SA); SHALENDRA KUMAR, AL-AHSA (SA); NAGIH MOHAMMED SHAALAN, AL-AHSA (SA); GHAZZAI ALMUTAIRI, AL-AHSA (SA); P.M.Z. HASAN, AL-AHSA (SA); THAMRAA ALSHAHRANI, AL-AHSA (SA)

(21) Appl. No.: 18/124,495

(22) Filed: Mar. 21, 2023

(51) Int. Cl. H01M 4/04; C23C 14/16; C23C 14/34; C23C 16/02; C23C 16/26; C23C 16/50; C23C 28/00; H01M 4/134; H01M 4/38; H01M 4/66; H01M 10/0525

(52) U.S. Cl. CPC H01M 4/0426; C23C 14/165; C23C 14/3464; C23C 16/0281; C23C 16/26; C23C 16/50; C23C 28/322; C23C 28/34; H01M 4/134; H01M 4/38; H01M 4/661; H01M 10/0525; H01M 2004/027

(57) ABSTRACT

A method of synthesizing a flexible and binder-free electrode material for lithium-ion batteries using multi-walled carbon nanotubes (MWCNTs) on copper (Cu) foil directly. The growth of MWCNTs is carried out by plasma-enhanced chemical vapor deposition (PECVD) using a sputter-coated chromium (Cr) barrier layer and a nickel (Ni) catalyst on Cu foil. The resultant electrode material can be used as a binder-free and flexible anode for lithium-ion batteries.

### BACKGROUND

### 1. Field

The disclosure of the present patent application relates to a method of synthesizing a flexible and binder-free electrode material for lithium-ion batteries using multi-walled carbon nanotubes (MWCNTs) on copper (Cu) foil directly.

### 2. Description of the Related Art

As we transition towards energy efficient green living, investments for the exploitation of renewable energy resources are increasing worldwide, with particular attention to wind and solar power energy plants. However, the intermittence of these resources requires high efficiency energy storage systems. Today the most convenient form of power source are the electrochemical cells/batteries that provide portability for chemical energy storage and its conversion to electrical energy by electrochemical oxidation and reduction reactions which occur at the electrodes. Additional benefits appear in the form of zero emissions and high energy conversion efficiency.

In addition, there is currently an enormous research effort aimed at developing ultrathin, flexible and soft batteries to cater to the bendable modern gadgets. The goal is improved rate capability without a penalty in charge capacity, and sufficient electrochemical cycling characteristics. Flexible batteries are not only needed, e.g., for rolled-up displays, active radio-frequency identification tags, integrated circuit smart cards and implantable medical devices, but there is also the intention to place large flexible batteries in hollow spaces of the auto body of future hybrid and electric vehicles. Of course, the battery performance is closely related to the structural and electrochemical properties of the applied electrodes. Further, electrodes are the main component used in batteries and supercapacitors. Hence, the development of flexible electrodes with high energy and power density and good rate capability which can function safely for many years becomes important.

Lithium-ion battery (LIB) applications have experienced significant growth over the past two decades. Today LIBs are widely used and denote the battery of choice for a wide range of applications, from portable electronics to electric vehicles.

Li-ion batteries (LIB) are preferred over other types of batteries because they have a long cycle life, broad temperature range of operation, low self-discharge rate, high performance in terms of capacity and energy density, and no memory effect. They are also referred to as rocking chair batteries as the lithium ions “rock” back and forth between the positive and negative electrodes as the cell is charged and discharged. Of the components, anode is one of the most critical parts in the proper functioning of the cells since it acts as a host for the Li ions.

Although LIBs have shown impressive commercial success, an understanding of the intrinsic functioning of LIB electrodes and of their constituent component materials still represents a subject of significant research. In recent years, the use of energy storage devices has expanded into new areas, including with uninterrupted power sources (UPS), stationary storage batteries (SSBs), and the automotive market, which encompasses both electric vehicles and hybrid electric vehicles.

Carbon is so far the most preferred material for LIB anode but its storage density, often called capacity, has a theoretical limit (in the case of graphite it is 372 mAhg⁻¹). Different metals like Sn. Al, Si etc. have therefore been investigated that can store far more lithium per gram by alloying with the latter. These, however, can be intrinsically unstable during cycling due to pulverization that causes large volume expansions (>250%), thus affecting the structural integrity of the anode. Moreover, the anode materials that are prepared in the powder form are usually coated onto a copper current collector to make them conductive and mechanically robust. This limits the flexibility of the electrode and adds to the dead weight of the cell.

Among various kinds of carbon materials, carbon nanotubes (CNTs) have attracted enormous interest for their use as electrodes for rechargeable batteries. In this regard, the carbon nanotubes are attractive due to their at times unique structure, high electrical conductivity, high aspect ratio (>1000), remarkable thermal conductivity, good capacity and good mechanical properties. The advantages of this type of carbon nanotubes/metal composite are the increased capacity of the metal alloying materials while using the carbon nanotubes as a scaffold to prevent pulverization and crumbling in the anode. A compound made of both metal and carbon nanotubes has two mechanisms to store lithium with, intercalation and alloying. In addition to increased capacity and better cycling, carbon nanotubes can act as a conductive wire to transport electrons. Moreover, the high tensile strength, high flexibility and high aspect ratio (>1000) of carbon nanotubes make them uniquely suited for making free standing, flexible anode material for lithium-ion cells.

Generally, CNT growth occurs on a SiO₂ surface using iron nanoparticles as a catalyst, with subsurface diffusion of iron catalyst particles occurring during chemical vapor deposition (CVD) growth due to the free energy of the iron nanoparticles covered with SiO₂ being lower than that with no diffusion. To use these CNTs, it is necessary to remove them from the SiO₂ substrate. However, when grown CNTs are removed from the SiO₂ surface, the iron nanoparticles at the bottom of the CNTs diffused into the SiO₂ are lifted with the CNTs, resulting in the formation of holes. However, if the catalyst particles adsorb strongly to the substrate, only the CNTs may be detached while the catalyst particles remain on the substrate surface. Thus, if the catalyst particles are adsorbing to the substrate surface, the density of CNTs grown will be higher.

Conventional methods for the fabrication of LIB electrodes which usually involve mixing, casting, and pressing the mixed constituents, including an anode material for lithium storage, a binder, such as polyvinylidene fluoride, to inhibit the collapse of the active materials from metal current collectors, and an electrical conductor to maintain the electrode conductivity onto the metal current collectors are typically used.

However, the binders and metal current collectors usually make no contribution to lithium storage, and the electrical conductor exhibits minimal lithium storage performance. Thus, these components significantly decrease the energy density of LIBs. Moreover, the presence of binders in the electrodes can decrease the accessible specific area of the active materials and increases the electrochemical polarization of the electrodes, undermining effective lithium-ion transport. It can also limit the working temperature range due to the thermal instability of the binder. The binder, electric conductor and the metal collectors together can constitute more than 20% of the total weight of the high-power cells, which is dead weight with no contribution to the cell capacity.

The optimization of the amount of binder to be added is very important. Each new material should be optimized separately. The optimization parameters depend on the particle size, agglomeration, surface properties etc.

Also, the electrodes are based on metal current collectors, which are not flexible because the active material layers are easily cracked or peeled off when metal current collectors are bent.

There are also other problems related to metallic current collectors (Cu in the case of anodes) like optimization of the surface polishing of the Cu for proper adhesion of the anode material, corrosion of the metal current collector when in contact with the electrolyte, increasing dead weight and increased cost, etc. Therefore, the development of a flexible, lightweight, binder-free, and current collector-free electrode configuration to increase the energy density is important.

Thus, a method for making a flexible and binder-free electrode material for lithium-ion batteries solving the aforementioned problems is desired.

### SUMMARY

The present subject matter relates to a method of making a flexible and binder-free electrode material for lithium-ion batteries using multi-walled carbon nanotubes (MWCNTs) on copper (Cu) foil directly. Accordingly, the present subject matter relates to the ability to grow carbon nanotubes (CNTs), such as MWCNTs, by using a chromium barrier layer in combination with a nickel catalyst on a copper foil substrate. With the ability to grow MWCNTs directly on the copper foil or substrate, there is no requirement to detach the MWCNTs, as the copper substrate is capable of conducting electricity, which is necessary for the current collector for batteries. Further, the nickel catalyst particles adsorb strongly on the copper foil or substrate surface, making the detachment of the MWCNTs from the copper substrate even less desirable.

In an embodiment, the present subject matter relates to a method for making a flexible and binder-free electrode material comprising: providing a copper (Cu) foil; depositing an electrically conductive chromium (Cr) thin barrier layer on a surface of the copper (Cu) foil; depositing a nickel (Ni) catalyst layer on a surface of the chromium (Cr) thin barrier layer opposite a surface of the chromium (Cr) thin barrier layer contacting the surface of the copper (Cu) foil; forming multi-walled carbon nanotubes (MWCNTs) on the copper (Cu) foil; and obtaining the flexible and binder-free electrode in the form of multi-walled carbon nanotubes (MWCNTs) on copper (Cu) foil.

In another embodiment, the present subject matter relates to an anode fabricated with a flexible and binder-free electrode material made according to the methods described herein. In a further embodiment, the present subject matter relates to an electrode for a lithium-ion cell or battery fabricated with a flexible and binder-free electrode material made according to the methods described herein. In yet another embodiment, the present subject matter relates to a lithium-ion cell or battery including an electrode fabricated with a flexible and binder-free electrode material made according to the methods described herein.

These and other features of the present subject matter will become readily apparent upon further review of the following specification and drawings.

### BRIEF DESCRIPTION OF THE DRAWINGS

FIG. 1 is a schematic representation of the growth of multi-walled carbon nanotubes (MWCNTs) on a copper (Cu) substrate using plasma enhanced chemical vapor deposition.

### DETAILED DESCRIPTION OF THE PREFERRED EMBODIMENTS

The following definitions are provided for the purpose of understanding the present subject matter and for construing the appended patent claims.

### Definitions

It should be understood that the drawings described above or below are for illustration purposes only. The drawings are not necessarily to scale, with emphasis generally being placed upon illustrating the principles of the present teachings. The drawings are not intended to limit the scope of the present teachings in any way.

Throughout the application, where compositions are described as having, including, or comprising specific components, or where processes are described as having, including, or comprising specific process steps, it is contemplated that compositions of the present teachings can also consist essentially of, or consist of, the recited components, and that the processes of the present teachings can also consist essentially of, or consist of, the recited process steps.

It is noted that, as used in this specification and the appended claims, the singular forms “a”, “an”, and “the” include plural references unless the context clearly dictates otherwise.

In the application, where an element or component is said to be included in and/or selected from a list of recited elements or components, it should be understood that the element or component can be any one of the recited elements or components, or the element or component can be selected from a group consisting of two or more of the recited elements or components. Further, it should be understood that elements and/or features of a composition or a method described herein can be combined in a variety of ways without departing from the spirit and scope of the present teachings, whether explicit or implicit herein.

The use of the terms “include,” “includes”. “including,” “have,” “has,” or “having” should be generally understood as open-ended and non-limiting unless specifically stated otherwise.

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a ±10% variation from the nominal value unless otherwise indicated or inferred.

The term “optional” or “optionally” means that the subsequently described event or circumstance may or may not occur, and that the description includes instances where said event or circumstance occurs and instances in which it does not.

Unless defined otherwise, all technical and scientific terms used herein have the same meaning as commonly understood to one of ordinary skill in the art to which the presently described subject matter pertains.

Where a range of values is provided, for example, concentration ranges, percentage ranges, or ratio ranges, it is understood that each intervening value, to the tenth of the unit of the lower limit, unless the context clearly dictates otherwise, between the upper and lower limit of that range and any other stated or intervening value in that stated range, is encompassed within the described subject matter. The upper and lower limits of these smaller ranges may independently be included in the smaller ranges, and such embodiments are also encompassed within the described subject matter, subject to any specifically excluded limit in the stated range. Where the stated range includes one or both of the limits, ranges excluding either or both of those included limits are also included in the described subject matter.

Throughout the application, descriptions of various embodiments use “comprising” language. However, it will be understood by one of skill in the art, that in some specific instances, an embodiment can alternatively be described using the language “consisting essentially of” or “consisting of”.

For purposes of better understanding the present teachings and in no way limiting the scope of the teachings, unless otherwise indicated, all numbers expressing quantities, percentages or proportions, and other numerical values used in the specification and claims, are to be understood as being modified in all instances by the term “about”. Accordingly, unless indicated to the contrary, the numerical parameters set forth in the following specification and attached claims are approximations that may vary depending upon the desired properties sought to be obtained. At the very least, each numerical parameter should at least be construed in light of the number of reported significant digits and by applying ordinary rounding techniques.

### Synthesis Process

In an embodiment, the present subject matter relates to a method for making a flexible and binder-free electrode material comprising: providing a copper (Cu) foil; depositing an electrically conductive chromium (Cr) thin barrier layer on a surface of the copper (Cu) foil; depositing a nickel (Ni) catalyst layer on a surface of the chromium (Cr) thin barrier layer opposite a surface of the chromium (Cr) thin barrier layer contacting the surface of the copper (Cu) foil; forming multi-walled carbon nanotubes (MWCNTs) on the copper (Cu) foil; and obtaining the flexible and binder-free electrode in the form of multi-walled carbon nanotubes (MWCNTs) on copper (Cu) foil.

In one aspect in this regard, the provided copper foil can be a commercial grade foil with a thickness of about 0.1 mm and a purity of about 99.9%. In further embodiments, the copper foil can be cleaned prior to use in the present methods. Such cleaning of the copper foil can include one or more of washing with deionized water, immersing in about 10% HCl solution, rinsing in deionized water, and drying with air flow. Should immersion in about 10% HCl be employed, this can be done for about 2-3 minutes.

In one important aspect, an electrically conductive chromium thin barrier layer is first formed or deposited on a surface of the copper foil. One non-limiting way in which the electrically conductive chromium thin barrier layer can be deposited on a surface of the copper foil is by placing the copper substrate in a sputter coater system to coat the copper foil. In this regard, the sputter coater is used to apply an ultra-thin coating of the nickel catalyst layer on the copper foil. The use of sputter coating can prevent charging of the product, increase thermal conduction, improve secondary electron emission, and protect beam sensitive specimens, all while conveying minimal heat transfer to the sample.

In an embodiment, the chromium is present as an electrically conductive thin barrier layer between the copper substrate and the nickel catalyst layer. In another embodiment, the chromium thin barrier layer can have a thickness of about 2-20 nm, about 5-10 nm, about 5 nm, about 6 nm, about 7 nm, about 8 nm, about 9 nm, or about 10 nm. In one embodiment in this regard, the chromium thin barrier layer can have a thickness of about 5-10 nm.

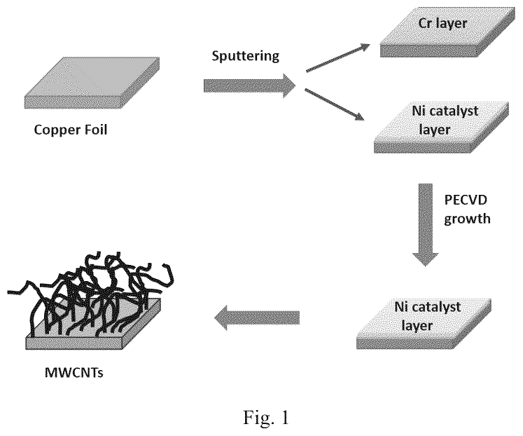

In another important aspect, a nickel (Ni) catalyst layer is formed or deposited on a surface of the chromium thin barrier layer opposite a surface of the chromium thin barrier layer contacting the surface of the copper foil. That is, as shown in FIG. 1, the electrically conductive chromium thin barrier layer is sandwiched between the copper foil and the nickel catalyst layer. One non-limiting way in which the nickel catalyst layer can be deposited on a surface of the electrically conductive chromium thin barrier layer is by placing the copper substrate in a sputter coater system to coat the copper foil. In this regard, the sputter coater is used to apply an ultra-thin coating of the nickel catalyst layer on the copper foil, and then to apply an ultra-thin coating of the chromium thin barrier layer on the nickel catalyst layer. The use of sputter coating can prevent charging of the product, increase thermal conduction, improve secondary electron emission, and protect beam sensitive specimens, all while conveying minimal heat transfer to the sample.

In an embodiment, the nickel catalyst layer can have a thickness of about 15-30 nm, about 20-25 nm, about 20 nm, about 21 nm, about 22 nm, about 23 nm, about 24 nm, or about 25 nm. In one embodiment in this regard, the nickel catalyst layer can have a thickness of about 20-25 nm.

In a further aspect, MWCNTs can be formed on the copper foil, thereby obtaining a flexible and binder-free electrode in the form of MWCNTs on copper foil. In one non-limiting example, the MWCNTs can be formed or grown on the copper foil using a plasma enhanced chemical vapor deposition (PECVD) process. The PECVD process is one commonly known to those of ordinary skill in the art, whereby thin films are deposited from a gas state to a solid state on a substrate. In certain non-limiting embodiments, a C₂H₂/NH₃, CH₄/NH₃. CH₄/H₂, or C₂H₂/H₂ feedstock can be used as the source of the carbon forming the MWCNTs. At the end of the growth period, the product is slowly cooled, within the furnace, under an H₂ gas environment to obtain the final product, in the form of a binder-free electrode for the fabrication of Li-ion batteries. The use of the PECVD process results in a high MWCNT deposition rate at a low processing temperature. By pre-processing the copper foil, it is possible to obtain a high-density population of catalyst particles, which can lead to the growth of highly dense MWCNTs.

In an embodiment, the MWCNTs formed on the copper substrate can have a diameter of about 5-20 nm, about 9-15 nm, about 9 nm, about 10 nm, about 11 nm, about 12 nm, about 13 nm, about 14 nm, or about 15 nm. In one embodiment in this regard, the MWCNTs can have a diameter of about 9-15 nm. Similarly, the MWCNTs formed on the copper substrate can have a length of about 5-20 μm, about 8-12 μm, about 8 μm, about 9 μm, about 10 μm, about 11 μm, or about 12 μm. In one embodiment in this regard, the MWCNTs can have a length of about 8-12 μm.

Once formed, the MWCNTs on copper foil can be used as binder-free and flexible anodes for Li-ion batteries. That is, by forming the MWCNTs directly on the copper foil, there is no need for a binder to fabricate electrodes, which is usually required in common electrodes for Li-ion batteries. In one non-limiting example, such Li-ion batteries can be used in electric vehicles (EV), as well as in other renewable technology products.

The present binder-free, flexible anodes made of MWCNTs on copper foil can provide excellent electrochemical performance and cyclic stability for hundreds of charge/discharge cycles.

The present methods will be better understood with reference to the following example.

### Example 1

### Use of MWCNTs on Copper Foil as an Anode in a Li-Ion Battery

Binder-free MWCNTs on Cu substrate was used as an anode. Lithium foil (Sigma Aldrich, Burlington, MA, United States, thickness 0.75 mm, width 45 mm, 99.9% trace metal basis) was used as a counter electrode, with a polypropylene membrane (25 μm, Celgard 2325) separator and 1 M lithium hexafluoro phosphate (LiPF₆) dissolved in ethylene carbonate (EC) and dimethyl carbonate (DMC) (1:1 in vol %) (all from Sigma Aldrich. Burlington. MA. United States, 99.9%) as the electrolyte. The coin cells (2032-type) were assembled in a glovebox at room temperature. Galvanostatic charge-discharge and cycling experiments were performed using a multi-channel battery tester (LAND) with a potential range between 0.0 and 2.8 V at a current density of 100 mAg⁻¹. An aging time of 12 h was used before starting the battery cycling. A Biologic SP-300 potentiostat was used to perform electrochemical impedance spectroscopies (EIS) between 200 kHz and 100 mHz using a sinusoidal perturbation at the amplitude of 10 mV. Cyclic voltammetry tests were carried out in a potential range of 0.0 to 3.0 V with various scan rates.

The studies showed that the battery fabricated using MWCNTs on Cu foil as an anode delivered a discharge capacity of 590 mAhg⁻¹ at a current density of 100 mAg⁻¹, and showed a capacity retention of 78% after 500 cycles of charge/discharge.

It is to be understood that the method for making binder-free, flexible anodes having MWCNTs on copper foil is not limited to the specific embodiments described above, but encompasses any and all embodiments within the scope of the generic language of the following claims enabled by the embodiments described herein, or otherwise shown in the drawings or described above in terms sufficient to enable one of ordinary skill in the art to make and use the claimed subject matter.

1. A method for making a flexible and binder-free electrode material comprising:
providing a copper (Cu) foil comprising a purity level of 99.9%;
depositing an electrically conductive chromium (Cr) thin barrier layer on a surface of the copper (Cu) foil comprising sputtering coating;
depositing a nickel (Ni) catalyst layer on a surface of the chromium (Cr) thin barrier layer opposite a surface of the chromium (Cr) thin barrier layer contacting the surface of the copper (Cu) foil;
forming multi-walled carbon nanotubes (MWCNTs) on the copper (Cu) foil using a plasma-enhanced chemical vapor deposition (PECVD) process; and obtaining the flexible and binder-free electrode in the form of multi-walled carbon nanotubes (MWCNTs) on copper (Cu) foil;
wherein the PECVD does not include DC biasing;
wherein the electrode is configured for use in batteries; and
wherein the electrode is a negative electrode.

2. (canceled)

3. The method according to claim 1, wherein the chromium (Cr) thin barrier layer has a thickness of about 5-10 nm.

4. The method according to claim 1, wherein said depositing of said nickel (Ni) catalyst layer comprises sputter coating the nickel (Ni) catalyst layer.

5. The method according to claim 4, wherein the nickel (Ni) catalyst 1 layer has a thickness of about 20-25 nm.

6. The method according to claim 1, wherein the multi-walled carbon nanotubes (MWCNTs) have a diameter of about 9-15 nm and a length of about 8-12 μm.

7. The method according to claim 1, wherein the electrode is an anode.

8. The method according to claim 1, wherein the copper (Cu) foil has a thickness of about 0.1 mm.

9. The method according to claim 1, wherein the provided copper (Cu) foil is first cleaned by washing with deionized water, immersing in 10% HCl solution for 2-3 minutes, rinsing in deionized water, and drying with airflow.

10-13. (canceled)
